(19) United States
(12) Patent Application Publication
(10) Pub. No.: US 2025/0275300 A1
(43) Pub. Date: Aug. 28, 2025

(54) DISPLAY DEVICE AND METHOD OF MANUFACTURING THE SAME

(71) Applicant: LG Display Co., Ltd., Seoul (KR)

(72) Inventor: Kanghyun KIM, Paju-si (KR)

(73) Assignee: LG Display Co., Ltd., Seoul (KR)

(21) Appl. No.: 18/926,168

(22) Filed: Oct. 24, 2024

(30) Foreign Application Priority Data
Feb. 23, 2024 (KR) 10-2024-0026207

(51) Int. Cl. H01L 33/22; H01L 25/16; H01L 33/00; H01L 33/38; H01L 33/60

(52) U.S. Cl. CPC H10H 20/82; H01L 25/167; H10H 20/013; H10H 20/018; H10H 20/8314; H10H 20/856

(57) ABSTRACT

A display device and a manufacturing method thereof are discussed. The display device can include a substrate in which a plurality of sub pixels is defined, and a light emitting diode which is disposed in each of the plurality of sub pixels and has a first uneven structure, the light emitting diode includes a first semiconductor layer which has a first uneven structure formed on a bottom surface, an emission layer on the first semiconductor layer, a second semiconductor layer on the emission layer, a first electrode disposed on at least a part of a side surface of the first semiconductor layer, and a second electrode disposed on the second semiconductor layer. Accordingly, the first uneven structure is formed below the light emitting diode to improve the light extraction efficiency of the light emitting diode.

### CROSS-REFERENCE TO RELATED APPLICATIONS

This application claims priority to Korean Patent Application No. 10-2024-0026207 filed on Feb. 23, 2024, in the Korean Intellectual Property Office, the entire contents of which is hereby expressly incorporated by reference into the present application.

### BACKGROUND

### Field

The present disclosure relates to a display device and a method of manufacturing the same, and more particularly to, a display device using a light emitting diode (LED) and a method of manufacturing the same.

### Discussion of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions, and a display device with a large display area and a reduced volume and weight is being studied.

Further, in recent years, a display device including a light emitting diode (LED) is attracting attention as a next generation display device. Since the LED is formed of an inorganic material, rather than an organic reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY OF THE DISCLOSURE

An object to be achieved by the present disclosure is to provide a display device which improves a yield of a self-assembly process of a light emitting diode and a method of manufacturing the display device.

Another object to be achieved by the present disclosure is to provide a display device in which a non-transferring defect which can be caused when a plurality of light emitting diodes is clustered together or bonded in an incorrect position is reduced, and a method of manufacturing the display device.

Still another object to be achieved by the present disclosure is to provide a display device which improves a light extraction efficiency by partially forming a ferromagnetic electrode having a low reflectance on a side surface of the light emitting diode, and a method of manufacturing the display device.

Still another object to be achieved by the present disclosure is to provide a display device which improves a light extraction efficiency by forming an uneven structure in a lower part and a side part of a light emitting diode, and a method of manufacturing the display device.

Still another object to be achieved by the present disclosure is to provide a display device in which a reflective partition is formed to enclose around a light emitting diode to reflect light extracted toward a side surface of the light emitting diode to an upper portion of the light emitting diode, and a method of manufacturing the display device.

Still another object to be achieved by the present disclosure is to provide a display device which reduces burrs of a first electrode and an encapsulation film of a light emitting diode, and a method of manufacturing the display device.

Still another object to be achieved by the present disclosure is to provide a display device which improves a light extraction efficiency of a light emitting diode to have a high efficiency and a high luminance, and a method of manufacturing the display device.

Objects of the present disclosure are not limited to the above-mentioned objects, and other objects, which are not mentioned above, can be clearly understood by those skilled in the art from the following descriptions.

According to an aspect of the present disclosure, a display device includes a substrate in which a plurality of sub pixels is defined; and a light emitting diode which is disposed in each of the plurality of sub pixels and has a first uneven structure, the light emitting diode includes: a first semiconductor layer which has a first uneven structure formed on a bottom surface; an emission layer on the first semiconductor layer; a second semiconductor layer on the emission layer; a first electrode disposed on at least a part of a side surface of the first semiconductor layer; and a second electrode disposed on the second semiconductor layer. Accordingly, the first uneven structure is formed below the light emitting diode to improve the light extraction efficiency of the light emitting diode.

According to an aspect of the present disclosure, a display device is provided. The display device comprises a substrate; and a plurality of sub pixels disposed on the substrate; wherein each of the plurality of sub pixels comprises a light emitting diode including: a first semiconductor layer having a bottom surface, a top surface and a side surface; an emission layer on the top surface; and a first electrode disposed on at least a part of the side surface; and the bottom surface has a first uneven structure. The first uneven structure can be an uneven structure formed by wet-etching using an alkaline etchant.

According to an aspect of the present disclosure, a method of manufacturing a display device includes placing a wafer and a plurality of light emitting diodes formed on one surface of the wafer in a chamber filled with a solution; separating the plurality of light emitting diodes from the wafer; placing an assembling substrate above the chamber; and moving the plurality of light emitting diodes to the assembling substrate by placing a magnet on the assembling substrate and self-assembling the plurality of light emitting diodes on the assembling substrate. Accordingly, in a state in which the plurality of light emitting diodes is disposed in the solution of the chamber, the light emitting diodes are separated from the wafer to relieve a shock to be applied to the plurality of light emitting diodes.

Other detailed matters of the example embodiments of the present disclosure are included in the detailed description and the drawings.

According to aspects of the present disclosure, a transferring process of a plurality of light emitting diodes is simplified to improve a yield of a display device.

According to aspects of the present disclosure, a defect that a light emitting diode is not transferred to a display panel caused when a plurality of light emitting diodes is clustered together or bonded in an incorrect position during a transferring process can be reduced.

According to aspects of the present disclosure, a ferromagnetic electrode having a low reflectance is formed on a side surface of a light emitting diode with a minimum area to improve a light extraction efficiency.

According to aspects of the present disclosure, an uneven structure is formed in a lower part and a side part of the light emitting diode to improve a light extraction efficiency.

According to aspects of the present disclosure, a light extraction efficiency of the light emitting diode is improved to implement a display device with a high efficiency and a high luminance.

According to aspects of the present disclosure, a display device which has a high efficiency and a high luminance to be driven with a low power can be implemented.

According to aspects of the present disclosure, reflective partition which encloses around the light emitting diode is formed to reflect light extracted toward a side surface of the light emitting diode to an upper portion of the light emitting diode and a luminance of the display device can be improved.

According to aspects of the present disclosure, burrs of the first electrode and the encapsulation film of the light emitting diode can be reduced.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an example embodiment of the present disclosure;

FIG. 2A is a partial cross-sectional view of a display device according to an example embodiment of the present disclosure;

FIG. 2B is a perspective view of a tiling display device according to an example embodiment of the present disclosure;

FIG. 3 is a cross-sectional view of a sub pixel of a display device according to an example embodiment of the present disclosure;

FIGS. 4A to 4H are process diagrams for explaining a method of manufacturing a display device according to an example embodiment of the present disclosure;

FIG. 5 is a cross-sectional view of a display device according to another example embodiment of the present disclosure;

FIGS. 6A to 6C are schematic plan views of a light emitting diode of a display device according to various example embodiments of the present disclosure;

FIG. 7 is a cross-sectional view of a display device according to still another example embodiment of the present disclosure;

FIG. 8 is a cross-sectional view of a display device according to still another example embodiment of the present disclosure; and

FIG. 9 is a cross-sectional view of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may.”

The features of various embodiments of the present disclosure can be partially or entirely adhered to or combined with each other and can be interlocked and operated in technically various ways, and the embodiments can be carried out independently of or in association with each other.

Hereinafter, various example embodiments of the present disclosure will be described in detail with reference to accompanying drawings. All the components of each display device according to all embodiments of the present disclosure are operatively coupled and configured.

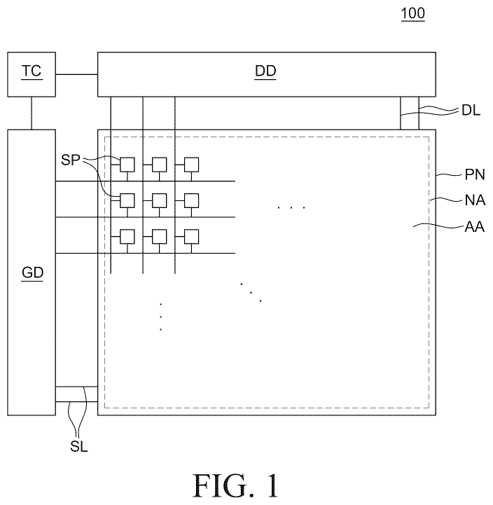

FIG. 1 is a schematic diagram of a display device according to an example embodiment of the present disclosure. In FIG. 1, for the convenience of description, among various components of a display device 100, a display panel PN, a gate driver GD, a data driver DD, and a timing controller TC are illustrated.

Referring to FIG. 1, the display device 100 includes the display panel PN including a plurality of sub pixels SP, the gate driver GD and the data driver DD which supply various signals to the display panel PN, and the timing controller TC which controls the gate driver GD and the data driver DD.

The gate driver GD supplies a plurality of scan signals to a plurality of scan lines SL according to a plurality of gate control signals supplied from the timing controller TC. Even though one gate driver GD is disposed to be spaced apart from one side of the display panel PN, the number of the gate drivers GD and the placement thereof are not limited thereto.

The data driver DD supplies a data voltage to a plurality of data lines DL according to a plurality of data control signals and image data supplied from the timing controller TC. The data driver DD converts the image data into a data voltage using a reference gamma voltage and can supply the converted data voltage to the plurality of data lines DL.

The timing controller TC aligns image data input from the outside to supply the image data to the data driver DD. The timing controller TC can generate a gate control signal and a data control signal using synchronization signals input from the outside, such as a dot clock signal, a data enable signal, and horizontal/vertical synchronization signals. Further, the timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to intersections of the scan lines SL and the data lines DL.

In the display panel PN, an active area AA (or display area) and a non-active area NA (or non-display area) can be defined. The non-active area NA can surround the active area AA entirely or only in part(s).

The active area AA is an area in which images are displayed in the display device 100. In the active area AA, a plurality of sub pixels SP which configures a plurality of pixels PX and a pixel (PX) circuit for driving the plurality of sub pixels SP can be disposed. The plurality of sub pixels SP is a minimum unit which configures the active area AA and n sub pixels SP can form one pixel PX. In each of the plurality of sub pixels SP, a thin film transistor, etc. for driving the plurality of light emitting diodes 120 can be disposed. The plurality of light emitting diodes 120 can be defined in different ways depending on the type of the display panel PN. For example, when the display panel PN is an inorganic light emitting display panel PN, the light emitting diode 120 can be a light emitting diode (LED) or a micro light emitting diode (LED).

In the active area AA, a plurality of signal lines which transmits various signals to the plurality of sub pixels SP is disposed. For example, the plurality of signal lines can include a plurality of data lines DL which supplies a data voltage to each of the plurality of sub pixels SP and a plurality of scan lines SL which supplies a scan signal to each of the plurality of sub pixels SP. The plurality of scan lines SL extends to one direction in the active area AA to be connected to the plurality of sub pixels SP. The plurality of data lines DL extends to a direction different from the one direction in the active area AA to be connected to the plurality of sub pixels SP. In addition, in the active area AA, a low potential power line, a high potential power line, and the like, can be further disposed, but are not limited thereto.

The non-active area NA is an area where images are not displayed so that the non-active area NA can be defined as an area extending from the active area AA. In the non-active area NA, a link line which transmits a signal to the sub pixel SP of the active area AA, a pad electrode, or a driving IC, such as a gate driver IC or a data driver IC, can be disposed.

In the meantime, the non-active area NA can be located on a rear surface of the display panel PN, for example, a surface on which the sub pixels SP are not disposed or can be omitted, and is not limited as illustrated in the drawing.

In the meantime, a driver, such as a gate driver GD, a data driver DD, and a timing controller TC, can be connected to the display panel PN in various ways. For example, the gate driver GD can be mounted in the non-active area NA in a gate in panel (GIP) manner or mounted between the plurality of sub pixels SP in the active area AA in a gate in active area (GIA) manner.

For example, the data driver DD and the timing controller TC are formed in separate flexible film and printed circuit board. The display panel PN is electrically connected to the data driver DD and the timing controller TC by bonding the flexible film and the printed circuit board to the pad electrode formed in the non-active area NA of the display panel PN.

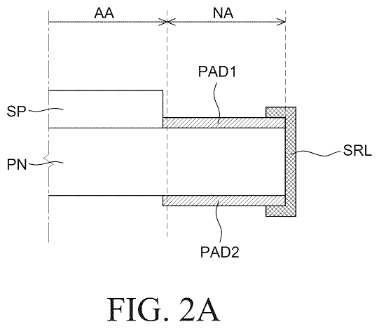

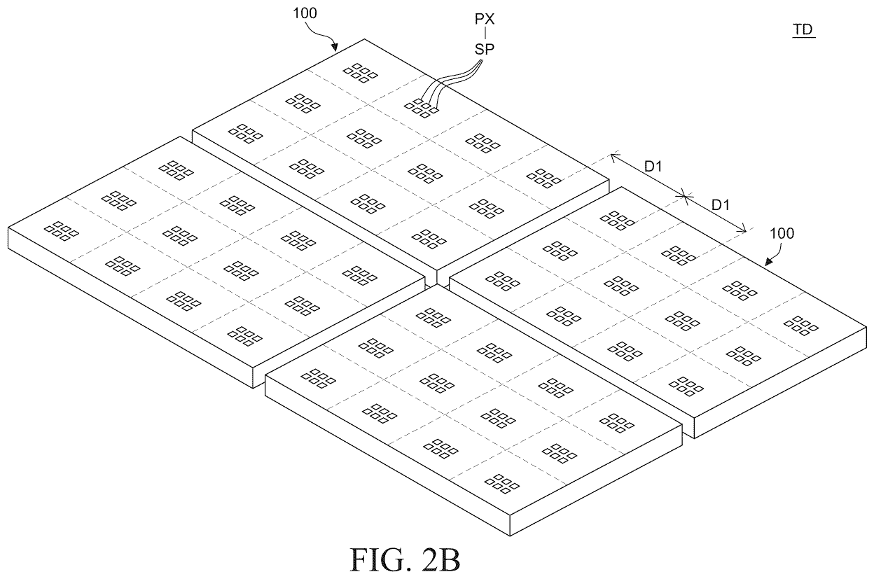

As another example, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA on the front surface of the display panel PN can be minimized. Therefore, when the gate driver GD, the data driver DD, and the timing controller TC are connected to the display panel PN as described above, a zero bezel in which there is no bezel can be substantially implemented, which will be described in more detail with reference to FIGS. 2A and 2B.

FIG. 2A is a partial cross-sectional view of a display device according to an example embodiment of the present disclosure. FIG. 2B is a perspective view of a tiling display device according to an example embodiment of the present disclosure.

In the non-active area NA of the display panel PN, a plurality of pad electrodes for transmitting various signals to the plurality of sub pixels SP is disposed. For example, in a non-active area NA on the front surface of the display panel PN, a first pad electrode PAD1 which transmits a signal to the plurality of sub pixels SP is disposed. In a non-active area NA on the rear surface of the display panel PN, a second pad electrode PAD2 which is electrically connected to a driving component, such as a flexible film and the printed circuit board, is disposed.

In this case, various signal lines connected to the plurality of sub pixels SP, for example, a scan line SL, a data line DL, or the like, extends from the active area AA to the non-active area NA to be electrically connected to the first pad electrode PAD1.

Further, the side line SRL is disposed along a side surface of the display panel PN. The side line SRL can electrically connect the first pad electrode PAD1 on the front surface of the display panel PN and the second pad electrode PAD2 on the rear surface of the display panel PN. Therefore, a signal from a driving component on the rear surface of the display panel PN can be transmitted to the plurality of sub pixels SP through the second pad electrode PAD2, the side line SRL, and the first pad electrode PAD1. Accordingly, a signal transmitting path is formed from the front surface of the display panel PN to the side surface and the rear surface to minimize an area of the non-active area NA on the front surface of the display panel PN.

Further, referring to FIG. 2B, a tiling display device TD having a large screen size can be implemented by connecting a plurality of display devices 100. At this time, as illustrated in FIG. 2A, when the tiling display device TD is implemented using a display device 100 with a minimized bezel, a seam area in which an image between the display devices 100 is not displayed is minimized so that a display quality can be improved.

For example, the plurality of sub pixels SP forms one pixel PX and a distance D1 between an outermost pixel PX of one display device 100 and an outermost pixel PX of another display device 100 adjacent to one display device can be implemented to be equal to a distance D1 between pixels PX in one display device 100. Accordingly, the distance between pixels PX between the display devices 100 is constantly configured to minimize the seam area.

However, FIGS. 2A and 2B are illustrative so that the display device 100 according to the example embodiment of the present disclosure can be a general display device with a bezel, but is not limited thereto.

Hereinafter, a display panel PN of a display device 100 according to an example embodiment of the present disclosure will be described in more detail.

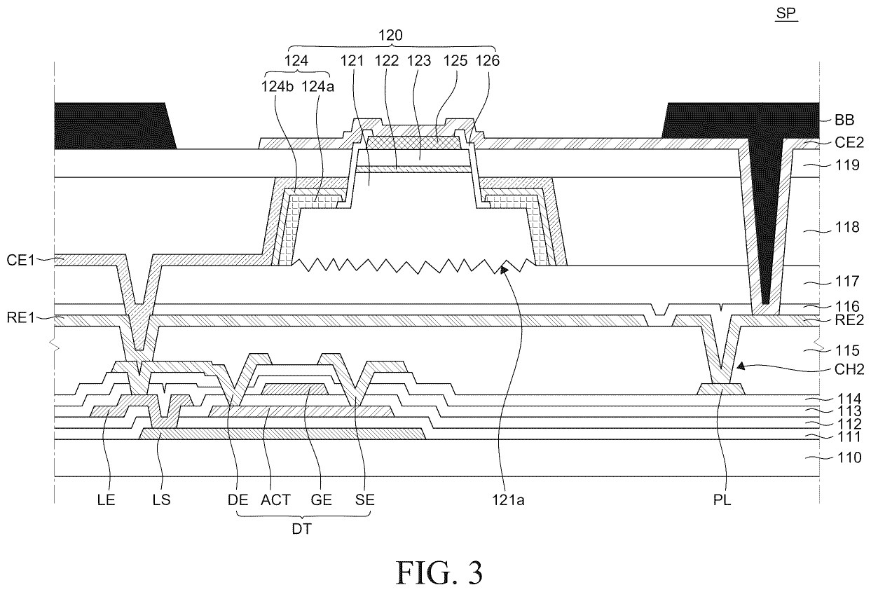

FIG. 3 is a cross-sectional view of a sub pixel of a display device according to an example embodiment of the present disclosure.

Referring to FIG. 3, the display panel PN of the display device 100 according to the example embodiment of the present disclosure includes a substrate 110, a buffer layer 111, a gate insulating layer 112, a first interlayer insulating layer 113, a second interlayer insulating layer 114, a first planarization layer 115, a passivation layer 116, an adhesive layer 117, a second planarization layer 118, a third planarization layer 119, a bank BB, a light shielding layer LS, a driving transistor DT, an auxiliary electrode LE, a power line PL, a plurality of reflective electrodes RE1 and RE2, a plurality of connection electrodes CE1 and CE2, and a light emitting diode 120.

The substrate 110 is a component for supporting various components included in the display device 100 and can be formed of an insulating material. For example, the substrate 110 can be formed of glass or resin. Further, the substrate 110 can be configured to include a polymer or plastics or can be formed of a material having flexibility.

A light shielding layer LS is disposed in each of the plurality of sub pixels SP on the substrate 110. The light shielding layer LS blocks light incident onto an active layer ACT of the driving transistor DT from the bottom of the substrate 110. Light which is incident onto the active layer ACT of the driving transistor DT is blocked by the light shielding layer LS to reduce a leakage current.

A buffer layer 111 is disposed on the substrate 110 and the light shielding layer LS. The buffer layer 111 can reduce permeation of moisture or impurities through the substrate 110. The buffer layer 111 can be configured by a single layer or a double layer of silicon oxide (SiOx) or silicon nitride (SiNx), but is not limited thereto. However, the buffer layer 111 can be omitted depending on a type of substrate 110 or a type of transistor, but is not limited thereto.

The driving transistor DT is disposed on the buffer layer 111. The driving transistor DT includes an active layer ACT, a gate electrode GE, a source electrode SE, and a drain electrode DE.

The active layer ACT is disposed on the buffer layer 111. The active layer ACT can be formed of a semiconductor material, such as an oxide semiconductor, amorphous silicon, or polysilicon, but is not limited thereto.

The gate insulating layer 112 is disposed on the active layer ACT. The gate insulating layer 112 is an insulating layer which insulates the active layer ACT from the gate electrode GE and can be configured by a single layer or a double layer of silicon oxide (SiOx) or silicon nitride (SiNx), but is not limited thereto.

The gate electrode GE is disposed on the gate insulating layer 112. The gate electrode GE can be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113 and the second interlayer insulating layer 114 are disposed on the gate electrode GE. In the first interlayer insulating layer 113 and the second interlayer insulating layer 114, a contact hole through which the source electrode SE and the drain electrode DE are connected to the active layer ACT is formed. The first interlayer insulating layer 113 and the second interlayer insulating layer 114 are insulating layers for protecting a component below the first interlayer insulating layer 113 and the second interlayer insulating layer 114 and can be configured by a single layer or a double layer of silicon oxide (SiOx) or silicon nitride (SiNx), but are not limited thereto.

The source electrode SE and the drain electrode DE which are electrically connected to the active layer ACT are disposed on the second interlayer insulating layer 114. The source electrode SE and the drain electrode DE can be configured by a conductive material, such as copper (Cu), aluminum (Al), molybdenum (Mo), nickel (Ni), titanium (Ti), chrome (Cr), or an alloy thereof, but are not limited thereto.

In the meantime, in the present disclosure, it is described that the first interlayer insulating layer 113 and the second interlayer insulating layer 114, for example, a plurality of insulating layers is disposed between the gate electrode GE and the source electrode SE and the drain electrode DE. However, only one insulating layer can be disposed between the gate electrode GE and the source electrode SE and the drain electrode DE, but are not limited thereto.

Further, a plurality of insulating layers, such as the first interlayer insulating layer 113 and the second interlayer insulating layer 114, is disposed between the gate electrode GE and the source electrode SE and the drain electrode DE. At this time, an electrode can be further: formed between the first interlayer insulating layer 113 and the second interlayer insulating layer 114. The additionally formed electrode can form a capacitor with the other configuration disposed below first interlayer insulating layer 113 or above the second interlayer insulating layer 114.

The auxiliary electrode LE is disposed on the gate insulating layer 112. The auxiliary electrode LE is an electrode which electrically connects the light shielding layer LS below the buffer layer 111 to any one of the source electrode SE and the drain electrode DE on the second interlayer insulating layer 114. For example, the light shielding layer LS is electrically connected to any one of the source electrode SE or the drain electrode DE through the auxiliary electrode LE so as not to operate as a floating gate. Therefore, fluctuation of a threshold voltage of the driving transistor DT caused by the floated light shielding layer LS can be reduced. Even though in the drawing, the light shielding layer LS is connected to the drain electrode DE, the light shielding layer LS can also be connected to the source electrode SE, but is not limited thereto.

The power line PL is disposed on the second interlayer insulating layer 114. The power line PL is electrically connected to the light emitting diode 120 together with the driving transistor DT to allow the light emitting diode 120 to emit light. The power line PL can be configured by a conductive material such as copper (Cu), aluminum (Al), molybdenum (Mo), nickel (Ni), titanium (Ti), chrome (Cr), or an alloy thereof, but is not limited thereto.

The first planarization layer 115 is disposed on the driving transistor DT and the power line PL. The first planarization layer 115 can planarize an upper portion of the substrate 110 on which the driving transistor DT is disposed. The first planarization layer 115 can be configured by a single layer or a double layer, and for example, can be formed of photoresist or an acrylic-based organic material, but is not limited thereto.

A plurality of reflective electrodes RE1 and RE2 which is spaced apart from each other is disposed on the first planarization layer 115. The plurality of reflective electrodes RE1 and RE2 electrically connects the light emitting diode 120 to the power line PL and the driving transistor DT and serves as a reflector which reflects light emitted from the light emitting diode 120 to the upper portion of the light emitting diode 120. The plurality of reflective electrodes RE1 and RE2 is formed of a conductive material having excellent reflecting property to reflect light emitted from the light emitting diode 120 toward the upper portion of the light emitting diode 120. For example, the plurality of reflective electrodes RE1 and RE2 can be formed of a metal material having an excellent reflective property, such as aluminum (Al), silver (Ag), copper (Cu), palladium (Pd), or an alloy thereof, but is not limited thereto.

The plurality of reflective electrodes RE1 and RE2 includes a first reflective electrode RE1 and a second reflective electrode RE2. The first reflective electrode RE1 can electrically connect the driving transistor DT and the light emitting diode 120. The first reflective electrode RE1 can be connected to the source electrode SE or the drain electrode DE of the driving transistor DT through a contact hole formed in the first planarization layer 115. Further, the first reflective electrode RE1 can be electrically connected to the first electrode 124 and the first semiconductor layer 121 of the light emitting diode 120 through a first connection electrode CE1 to be described below.

The second reflective electrode RE2 can electrically connect the power line PL and the light emitting diode 120. The second reflective electrode RE2 is connected to the power line PL through a contact hole formed in the first planarization layer 115 and is electrically connected to a second electrode 125 and a second semiconductor layer 123 of the light emitting diode 120 through a second connection electrode CE2 to be described below.

The first reflective electrode RE1 or the second reflective electrode RE2 are formed to overlap the entire area of the light emitting diode 120 below the light emitting diode 120 to reflect light from the light emitting diode 120. For example, the first reflective electrode RE1 is disposed so as to overlap the overall light emitting diode 120 and light directed to the bottom of the light emitting diode 120 can be reflected to the top of the substrate 110 by the first reflective electrode RE1. However, instead of the first reflective electrode RE1, the second reflective electrode REZ can be disposed so as to overlap the overall light emitting diode 120, but is not limited thereto.

The passivation layer 116 is disposed on the plurality of reflective electrodes RE1 and RE2. In the passivation layer 116, a contact hole through which the first connection electrode CE1 is connected to the first reflective electrode RE1 and a contact hole through which the second connection electrode CE2 is connected to the second reflective electrode RE2 can be formed. The passivation layer 116 is an insulating layer which protects components below the passivation layer 116 and can be configured by a single layer or a double layer of silicon oxide (SiOx) or silicon nitride (SiNx), but is not limited thereto.

The adhesive layer 117 is disposed on the plurality of reflective electrodes RE1 and RE2 and the passivation layer 116. The adhesive layer 117 is coated on the front surface of the substrate 110 to fix the light emitting diode 120 disposed on the adhesive layer 117. For example, the adhesive layer 117 can be selected from any one of adhesive polymer, epoxy resist, UV resin, polyimide, acrylate, urethane, and polydimethylsiloxane (PDMS), but is not limited thereto.

The plurality of light emitting diodes 120 is disposed in each of the plurality of sub pixels SP on the adhesive layer 117. The plurality of light emitting diodes 120 is an element which emits light by a current. The plurality of light emitting diodes 120 can include a light emitting diode 120 which emits red light, green light, and blue light and implement various colored light including white by a combination thereof. For example, the plurality of light emitting diodes 120 can be a light emitting diode (LED) or a micro LED, but is not limited thereto.

The light emitting diode 120 includes a first semiconductor layer 121, an emission layer 122, a second semiconductor layer 123, a first electrode 124, a second electrode 125, and an encapsulation film 126. The first electrode 124 can include a first electrode layer 124a and a second electrode layer 124b.

The first semiconductor layer 121 is disposed on the adhesive layer 117 and the second semiconductor layer 123 is disposed on the first semiconductor layer 121. The first semiconductor layer 121 and the second semiconductor layer 123 can be layers formed by doping n-type and p-type impurities into a specific material. For example, the first semiconductor layer 121 and the second semiconductor layer 123 can be layers doped with n-type and p-type impurities into a material such as gallium nitride (GaN), indium aluminum phosphide (InAlP), or gallium arsenide (GaAs). The p-type impurity can be magnesium (Mg), zinc (Zn), beryllium (Be), etc., and the n-type impurity can be silicon (Si), germanium (Ge), tin (Sn), etc., but are not limited thereto.

At this time, the first semiconductor layer 121 can include a part which protrudes to an outside of the second semiconductor layer 123 and the emission layer 122. The first semiconductor layer 121 is formed by a part which overlaps the second semiconductor layer 123 and the emission layer 122 and a remaining part which encloses the part but does not overlap the second semiconductor layer 123 and the emission layer 122. Therefore, a part of a top surface of the first semiconductor layer 121 can be exposed from the second semiconductor layer 123 and the emission layer 122.

Further, a first uneven structure 121a can be formed on a bottom surface of the first semiconductor layer 121. A roughness of the bottom surface of the first semiconductor layer 121 can be increased by forming the first uneven structure 121a on the bottom surface of the first semiconductor layer 121 of the light emitting diode 120. Therefore, when the light emitting diode 120 is self-assembled, a defect that the light emitting diode 120 is adhered in an irregular position or the light emitting diode 120 is not picked up can be reduced. Further, a light extraction efficiency of the light emitting diode 120 can be improved, which will be described in more detail below.

The emission layer 122 is disposed between the first semiconductor layer 121 and the second semiconductor layer 123. The emission layer 122 is supplied with holes and electrons from the first semiconductor layer 121 and the second semiconductor layer 123 to emit light. The emission layer 122 can be formed by a single layer or a multi-quantum well (MQW) structure, and for example, can be formed of indium gallium nitride (InGaN) or gallium nitride (GaN), but is not limited thereto.

The first electrode 124 is disposed on a side surface of the first semiconductor layer 121. The first electrode 124 can be disposed on all or a part of the side surface of the first semiconductor layer 121. Further, the first electrode 124 can be disposed on a top surface of the first semiconductor layer 121 which is exposed from the second semiconductor layer 123 and the emission layer 122. The first electrode 124 can be disposed to extend from the side surface of the first semiconductor layer 121 to the top surface of the first semiconductor layer 121. Further, an end portion of the first electrode 124 can be disposed on the top surface of the first semiconductor layer 121. The first electrode 124 includes a first electrode layer 124a and a second electrode layer 124b.

The first electrode layer 124a is an electrode for electrically connecting the light emitting diode 120 and the driving transistor DT. The first electrode layer 124a can be configured by an opaque conductive material, such as titanium (Ti), gold (Au), silver (Ag), copper (Cu) or an alloy thereof, a transparent conductive material, such as indium tin oxide (ITO) or indium zinc oxide (IZO), or a combination of the opaque conductive material and the transparent conductive material. However, it is not limited thereto.

The second electrode layer 124b is disposed on the first electrode layer 124a. The second electrode layer 124b can be disposed so as to enclose the side surface of the first semiconductor layer 121 and the first electrode layer 124a. The second electrode layer 124b can be disposed on the side surface of first semiconductor layer 121 so as to cover the first electrode layer 124a. Further, an end portion of the second electrode layer 124b can be disposed so as to cover the top surface of the first semiconductor layer 121 and the end portion of the first electrode layer 124a disposed on the top surface of the first semiconductor layer 121.

The second electrode layer 124b is an electrode which induces self-assembly of the light emitting diode 120 by forming an attractive force with the magnet MG during the self-assembly of the light emitting diode 120. The second electrode layer 124b can be formed of a ferromagnetic material and for example, can be formed of a ferromagnetic material, such as iron (Fe), cobalt (Co), or nickel (Ni). Further, the second electrode layer 124b further includes a layer formed of a ferromagnetic material and an opaque conductive material having a high reflectance to be formed with a double-layered structure. In this case, some of light directed to a side surface, among light emitted from the light emitting diode 120 is reflected from the first electrode layer 124a and the second electrode layer 124b to be directed to the top of the light emitting diode 120.

In the meantime, the first electrode layer 124a and the second electrode layer 124b disposed on a side portion of the first semiconductor layer 121 can be disposed in an area between the top surface of the first semiconductor layer 121 and the side surface of the first semiconductor layer 121, due to a margin of a process of etching the first electrode layer 124a and the second electrode layer 124b. For example, one end and the other end of the first electrode layer 124a are disposed on a top surface and a side surface of the first semiconductor layer 121. Further, one end and the other end of the second electrode layer 124b can be also disposed on a top surface and a side surface of the first semiconductor layer 121. Specifically, it is difficult to perform the etching to remain the first electrode layer 124a and the second electrode layer 124b only on the side surface of the first semiconductor layer 121 due to the process error and a characteristic of process equipment.

Therefore, the etching process is performed to remain a part of the first electrode layer 124a and the second electrode layer 124b disposed between the top surface of the first semiconductor layer 121 and a lower edge of the first semiconductor layer 121. Therefore, the first electrode layer 124a and the second electrode layer 124b can be also formed on the side surface of the first semiconductor layer 121. Accordingly, the etching process is performed on the top surface of the first semiconductor layer 121 to form the first electrode layer 124a and the second electrode layer 124b also on the side surface of the first semiconductor layer 121.

The second electrode 125 is disposed on the top surface of the second semiconductor layer 123. The second electrode 125 is an electrode which electrically connects a second connection electrode CE2 to be described below and the second semiconductor layer 123. For example, the second electrode 125 is formed of a transparent conductive material, such as indium tin oxide (ITO) or indium zinc oxide (IZO), but is not limited thereto.

An encapsulation film 126 which encloses at least a part of the first semiconductor layer 121, the emission layer 122, the second semiconductor layer 123, and the second electrode 125 is disposed. The encapsulation film 126 is formed of an insulating material to protect the first semiconductor layer 121, the emission layer 122, and the second semiconductor layer 123. The encapsulation film 126 can cover an upper portion of the first semiconductor layer 121 adjacent to the emission layer 122, a side surface of the emission layer 122, a side surface of the second semiconductor layer 123, and a part of an edge of the second electrode 125. A part of the second electrode 125 is exposed from the encapsulation film 126 to electrically connect the second connection electrode CE2 and the second electrode 125.

Further, the encapsulation film 126 is disposed so as to cover an upper portion of the first semiconductor layer 121 adjacent to the emission layer 122, for example, the side surface of the first semiconductor layer 121 adjacent to the emission layer 122 and a part of the top surface of the first semiconductor layer 121 which protrudes to the outside of the emission layer 122. In this case, the encapsulation film 126 is disposed between an end portion of the second electrode layer 124b and an end portion of the first electrode layer 124a and a part of the top surface of the first semiconductor layer 121 and between an end portion of the second electrode layer 124b and an end portion of the first electrode layer 124a and an upper side surface of the first semiconductor layer 121. By doing this, the second electrode layer 124b and the first electrode layer 124a are not in contact with the emission layer 122 and the second semiconductor layer 123 and a short circuit defect can be suppressed. The encapsulation film 126 can be formed of any one of insulating materials, such as silicon oxide (SiOx) or silicon nitride (SiNx), but is not limited thereto.

Next, the first connection electrode CE1 is disposed on the adhesive layer 117 and the light emitting diode 120. The first connection electrode CE1 is an electrode which is disposed in each of the plurality of sub pixels SP to electrically connect the light emitting diode 120 and the driving transistor DT.

The first connection electrode CE1 can be electrically connected to the first reflective electrode RE1 through a contact hole formed in the adhesive layer 117 and the passivation layer 116. Accordingly, the first connection electrode CE1 can be electrically connected to any one of the source electrode SE and the drain electrode DE of the driving transistor DT through the first reflective electrode RE1.

Further, the first connection electrode CE1 can be electrically connected to the first electrode layer 124a and the second electrode layer 124b of each of the plurality of light emitting diodes 120. The first connection electrode CE1 can be disposed so as to enclose the side surface of the light emitting diode 120. The first connection electrode CE1 can be disposed so as to enclose the side surface of the first semiconductor layer 121, a top surface of the first semiconductor layer 121 protruding to the outside of the second semiconductor layer 123, the first electrode layer 124a, and the second electrode layer 124b. The first connection electrode CE1 can be disposed so as to enclose the lower side surface of the light emitting diode 120. The first connection electrode CE1 is in contact with the second electrode layer 124b to be electrically connected to the first electrode layer 124a and the first semiconductor layer 121.

In summary, the first connection electrode CE1 can be electrically connected to the first reflective electrode RE1 and the driving transistor DT. The first connection electrode CE1 is disposed so as to cover a side portion of the first semiconductor layer 121 in which the first electrode layer 124a and the second electrode layer 124b are formed to be electrically connected to the first electrode layer 124a and the second electrode layer 124b. Therefore, the driving transistor DT and the first electrode layer 124a and the first semiconductor layer 121 of the light emitting diode 120 can be electrically connected by means of the first connection electrode CE1 and the first reflective electrode RE1.

The second planarization layer 118 is disposed on the first connection electrode CE1 and the light emitting diode 120. The third planarization s disposed on the second planarization layer 118. The second planarization layer 118 and the third planarization layer 119 planarize an upper portion of the substrate 110 on which the light emitting diode 120 is disposed and fix the light emitting diode 120 onto the substrate 110 together with the adhesive layer 117. The second planarization layer 118 overlaps a part of side surfaces of the plurality of light emitting diodes 120 to fix and protect the plurality of light emitting diodes 120.

A thickness of the second planarization layer 118 can be smaller than a thickness of the first semiconductor layer 121 of the light emitting diode 120. For example, the top surface of the second planarization layer 118 can be disposed below the emission layer 122. When the display device 100 is manufactured, the self-alignment can be performed by adjusting the thickness of the second planarization layer 118 to electrically connect the first connection electrode CE1 only to the first semiconductor layer 121. For example, a process of aligning the first electrode layer 124a of the light emitting diode 120 and the first connection electrode CE1 is omitted and the first electrode 124 and the first connection electrode CEL are connected to each other by a self-alignment method, which will be described in more detail below.

The top surface of the third planarization layer 119 can be disposed to be higher than at least the emission layer 122 of the light emitting diode 120. Further, the top surface of the third planarization layer 119 can be disposed at a height which is equal to or lower than the top surface of the second semiconductor layer 123. For example, a top surface of the third planarization layer 119 can be disposed between the top surface of the emission layer 122 and the top surface of the second semiconductor layer 123 or on the same planar surface as the top surface of the second semiconductor layer 123. At this time, when the display device 100 is manufactured, the self-alignment can be performed so that the second connection electrode CE2 can be electrically connected only to the second semiconductor layer 123 using the third planarization layer 119. For example, a process of aligning the second electrode 125 of the light emitting diode 120 and the second connection electrode CE2 is omitted and the second electrode 125 and the second connection electrode CE2 can be connected to each other by a self-alignment method, which will be described in more detail below.

Next, the second connection electrode CE2 is disposed on the third planarization layer 119. The second connection electrode CE2 is an electrode for electrically connecting the light emitting diode 120 and the power line PL. The second connection electrode CE2 can be electrically connected to the power line PL through a contact hole formed in the third planarization layer 119, the second planarization layer 118, the adhesive layer 117, and the passivation layer 116. Further, the second connection electrodes CE2 are in contact with the top surface of the second electrode 125 which is exposed from the second planarization layer 118 to be electrically connected to the second electrode 125 of the light emitting diode 120 and the second semiconductor layer 123. Accordingly, the second electrode 125 of the light emitting diode 120 and the second semiconductor layer 123 and the power line PL can be electrically connected to each other by means of the second connection electrode CE2.

The bank BB is disposed on the third planarization layer 119 and the second connection electrode CE2. The bank BB can be disposed to be spaced apart from the light emitting diode 120 with a predetermined interval. The bank BB can cover a part of the second connection electrode CE2. The bank BB is disposed at the boundary between the sub pixels SP which are adjacent to each other to reduce the mixture of light emitted from the light emitting diode 120 of each of the plurality of sub pixels SP. The bank BB can include an opaque material and a black component to reduce color mixture between the plurality of sub pixels SP and for example, can be formed of black resin, but is not limited thereto.

In the meantime, a protection layer can be further disposed on the bank BB. The protection layer is a layer for protecting configurations below the protection layer. The protection layer can be configured by a single layer or a double layer, and for example, configured by benzocyclobutene, a light-transmitting epoxy, a photoresist, or an acrylic-based organic material, but is not limited thereto.

Hereinafter, a method of manufacturing the display device 100 according to an example embodiment of the present disclosure will be described.

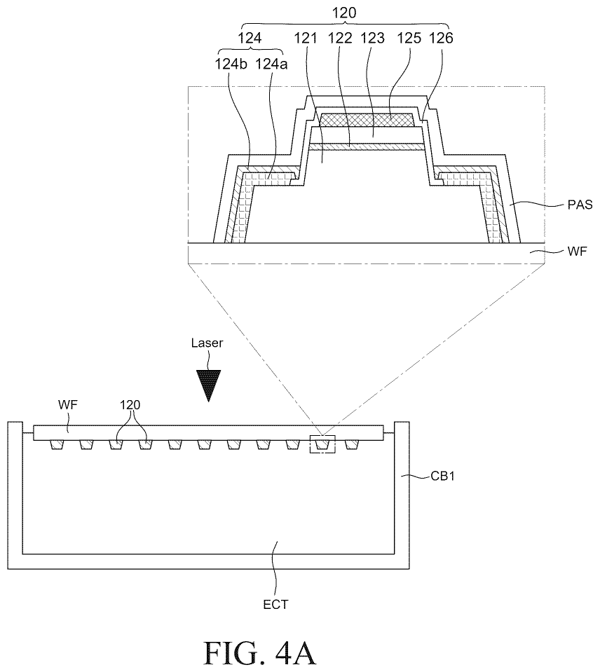

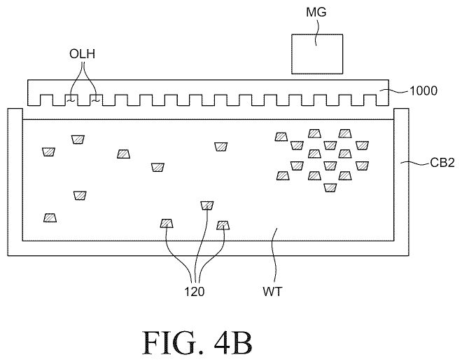

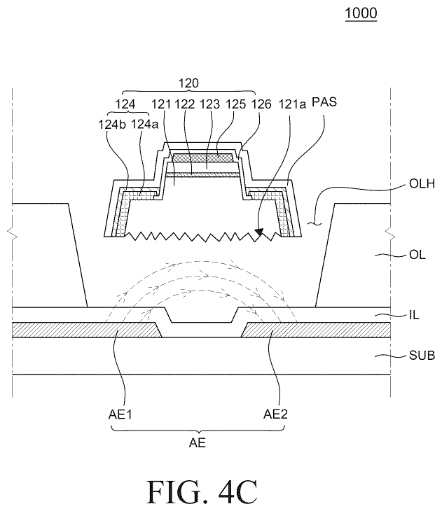

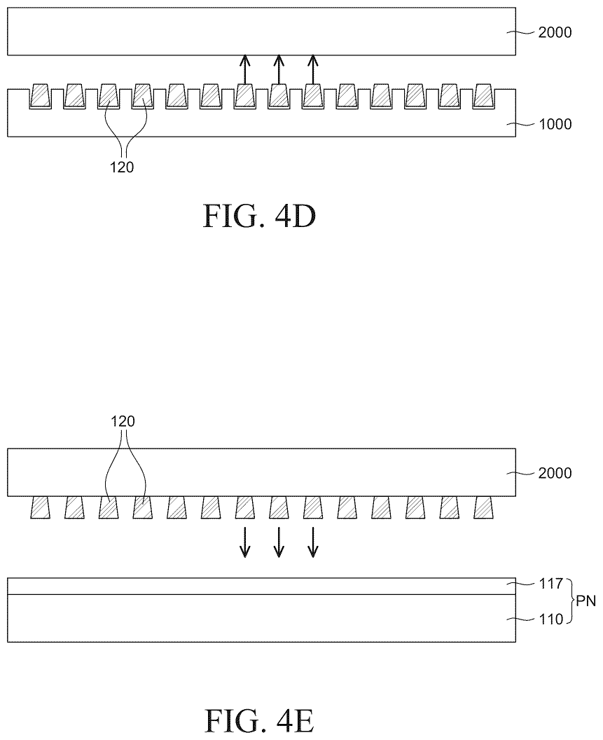

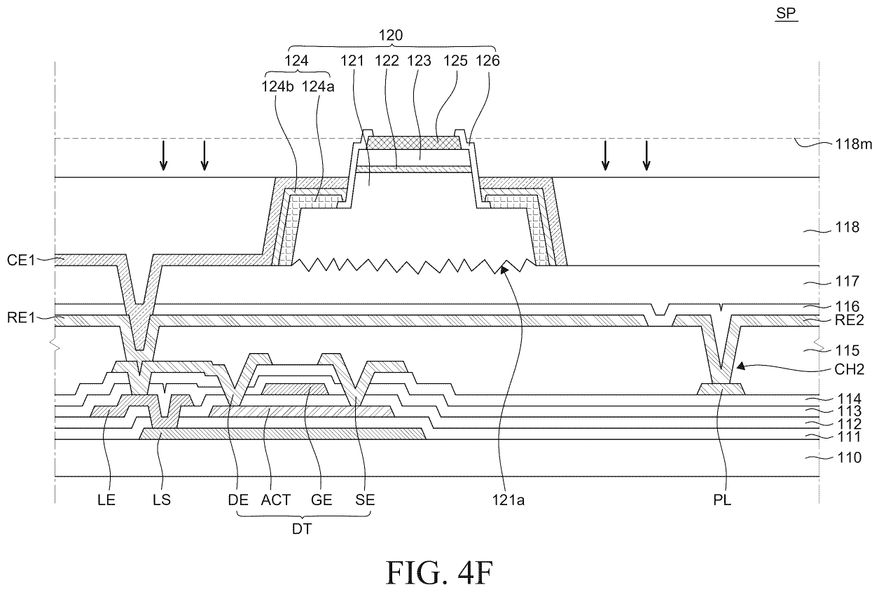

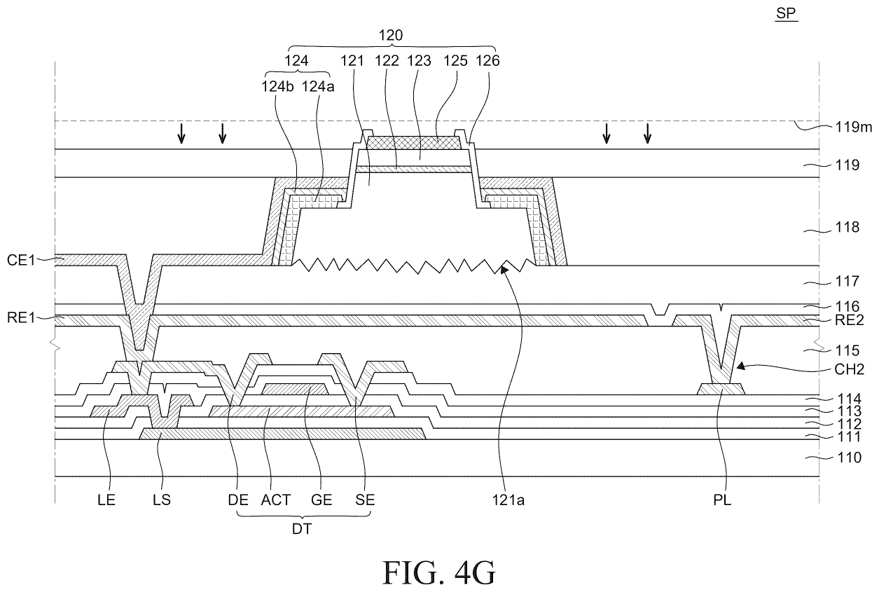

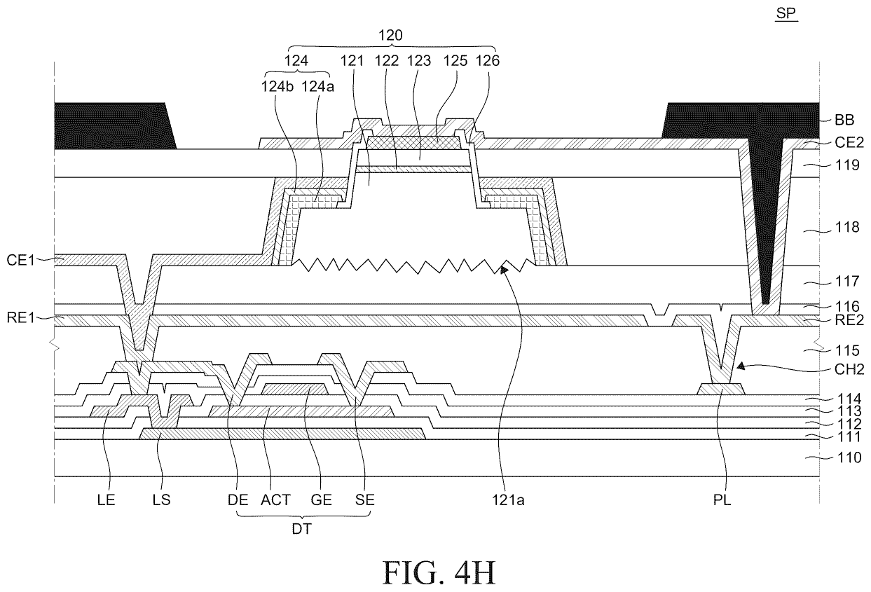

FIGS. 4A to 4H are process diagrams for explaining a method of manufacturing a display device according to an example embodiment of the present disclosure. FIGS. 4A to 4E are process diagrams for explaining a process of self-assembling the light emitting diode 120 and transferring the light emitting diode onto the display panel PN, and FIGS. 4F to 4H are process diagrams for explaining a process after transferring the light emitting diode 120 onto the display panel PN.

Referring to FIG. 4A, a plurality of light emitting diodes 120 is formed on a wafer WF and is separated from the wafer WF. The plurality of light emitting diodes 120 which is separated from the wafer WF is disposed in a first chamber CB1 filled with a solution ECT to remove a residual film below the first semiconductor layer 121 and form a first uneven structure 121a.

First, an epitaxial layer is grown on the wafer WF and is patterned into a plurality of parts to form a first semiconductor layer 121, an emission layer 122, and a second semiconductor layer 123 of the plurality of light emitting diodes 120. Next, the second electrode 125 is formed on the second semiconductor layer 123 and an encapsulation film 126 covers the second electrode 125, the second semiconductor layer 123, and the emission layer 122, and an upper portion of the first semiconductor layer 121. Next, the first electrode layer 124a and the second electrode layer 124b are formed on a side portion of the first semiconductor layer 121 exposed from the encapsulation film 126 to form a plurality of light emitting diodes 120. Accordingly, end portions of the first electrode layer 124a and the second electrode layer 124b can cover a part of the encapsulation film 126 disposed on the top surface of the first semiconductor layer 121.

Further, before separating the plurality of light emitting diodes 120 from the wafer WF, a protection film PAS which covers the light emitting diode 120 can be formed. The protection film PAS is disposed so as to cover the light emitting diode 120 to protect the plurality of light emitting diodes 120 during the processing process. For example, the protection film PAS is disposed so as to cover an upper portion and a side portion of the light emitting diode 120 and cover the first electrode layer 124a, the second electrode layer 124b, and the encapsulation film 126. The protection film PAS is formed of an insulating material, and for example, formed of an insulating material, such as silicon oxide (SiOx), but is not limited thereto.

Next, the plurality of light emitting diodes 120 on which the protection film PAS is formed can be separated from the wafer WF. The wafer WF and the plurality of light emitting diodes 120 can be separated by various methods, and for example, can be separated using a laser lift-off (LLO) method. For example, the laser lift-off (LLO) method, the laser is irradiated onto a rear surface of the wafer WF in a state in which the plurality of light emitting diodes 120 of the wafer WF and the first chamber CB1 are disposed to be opposite to each other to separate the wafer WF and the light emitting diode 120.

Next, the plurality of light emitting diodes 120 which is separated from the wafer WF is injected in the first chamber CB1 filled with the solution ECT to remove a residual film on the bottom surface of the first semiconductor layer 121 and can form the first uneven structure 121a. Specifically, the plurality of light emitting diodes 120 can be separated in a state in which one surface of the wafer WF on which the plurality of light emitting diodes 120 is formed is disposed to be opposite to the first chamber CB1. The plurality of light emitting diodes 120 separated from the wafer WF can be injected into the first chamber CB1 filled with the solution ECT. For example, the wafer WF and the light emitting diode 120 can be separated in a state in which the light emitting diode 120 is located on the solution ECT. As another example, the wafer WF and the light emitting diode 120 can be separated in a state in which the light emitting diode 120 is located in the solution ECT. Further, in a state in which the light emitting diode 120 is located in the solution ECT, for example, in a state in which at least a part of the wafer WF is disposed in the first chamber CB1, for example, if the light emitting diode 120 is separated by the laser lift-off (LLO) method, a shock applied to the light emitting diode 120 when the light emitting diode 120 and the wafer WF are separated can be relieved. At this time, the solution ECT can include various types of solvents or solutions. For example, the solution ECT can include de-ionized water (DI water) or an alkaline etchant such as KOH solution.

Next, a part of the light emitting diode 120 exposed from the protection film PAS can be wet-etched by the solution ECT. In this case, the solution ECT can include the KOH etchant. For example, a bottom surface of the first semiconductor layer 121 exposed from the protection film PAS can be wet-etched by the solution ECT. During this process, a gallium (Ga) residual film of the bottom surface of the first semiconductor layer 121 is removed and the first uneven structure 121a can be formed. During the process of separating the light emitting diode 120 and the wafer WF, laser can be irradiated onto the bottom surface of the light emitting diode 120 which is in contact with the wafer WF, for example, the bottom surface of the first semiconductor layer 121. The first semiconductor layer 121 can be formed of gallium nitride (GaN). When the laser is irradiated onto the bottom surface of the first semiconductor layer 121, a part of the lower portion of the first semiconductor layer 121 can be decomposed into gallium and nitrogen. Nitrogen is converted into gas and gallium can remain in a lower portion of the first semiconductor layer as a residual film. Accordingly, the light emitting diode 120 is injected into the solution ECT to remove the gallium residual film of the bottom surface of the semiconductor layer.

Further, the gallium residual film of the bottom surface of the first semiconductor layer 121 exposed from the protection film PAS and the bottom surface of the first semiconductor layer 121 is irregularly etched, simultaneously, to form the first uneven structure 121a. For example, the solution ECT is configured to be an alkaline etchant such as KOH etchant to irregularly etch the bottom surface of the first semiconductor layer 121 and the process time is adjusted to adjust a roughness of the bottom surface of the first semiconductor layer 121.

Referring to FIG. 4B, when the formation of the first uneven structure 121a below the first semiconductor layer 121 is completed, the plurality of light emitting diodes 120 is washed and the plurality of light emitting diodes 120 is self-assembled on an assembling substrate 1000.

First, the plurality of light emitting diodes 120 is injected into a cleaning solution to wash the plurality of light emitting diodes 120. For example, the cleaning solution can be de-ionized water (DI water). Accordingly, foreign materials generated from the etching process or the LLO process can be removed by the cleaning process.

Further, the plurality of light emitting diodes 120 can be injected into the second chamber CB2 filled with fluid WT. The fluid WT can include various types of solvents or solutions. For example, the fluid WT can be formed of the same material as the solution ECT. As another example, the fluid WT can be de-ionized water (DI water) and a second chamber CB2 filled with fluid WT can be a top-open type.

Next, the assembling substrate 1000 can be located on the second chamber CB2 filled with the light emitting diode 120. The assembling substrate 1000 can be disposed such that an organic layer OL on which a plurality of openings OLH of the assembling substrate 1000 is formed and the second chamber CB2 are opposite to each other.

Next, a magnet MG can be located on the assembling substrate 1000. The light emitting diodes 120 sinking on the bottom of the second chamber CB2 or floating can move toward the assembling substrate 1000 by a magnetic force of the magnet MG.

At this time, the light emitting diode 120 can include magnetic materials to move by the magnetic field. For example, the second electrode layer 124b of the light emitting diode 120 includes a ferromagnetic material, such as iron (Fe), cobalt (Co), or nickel (Ni) to move the light emitting diode 120 to the magnet MG.

Referring to FIG. 4C, the light emitting diode 120 which moves to the assembling substrate 1000 by the magnet MG can be self-assembled to the assembling substrate 1000 by an electric field formed between a plurality of assembly electrodes AE.

The assembling substrate 1000 includes an assembly substrate SUB, a plurality of assembly electrodes AE, an assembly insulating layer IL, and an organic layer OL.

A plurality of assembly electrodes AE is disposed on the assembly substrate SUB. The plurality of assembly electrodes AE includes a plurality of first assembly electrodes AE1 and a plurality of second assembly electrodes AE2. The plurality of first assembly electrodes AE1 and the plurality of second assembly electrodes AE2 can be disposed to be spaced apart from each other with a predetermined interval. The plurality of first assembly electrodes AE1 and the plurality of second assembly electrodes AE2 can be alternately disposed. The plurality of first assembly electrodes AE1 and the plurality of second assembly electrodes AE2 are applied with different voltages so that an electric field can be formed between the plurality of first assembly electrodes AE1 and the plurality of second assembly electrodes AE2. Further, the plurality of light emitting diodes 120 can be self-assembled in an area between the plurality of first assembly electrodes AE1 and the plurality of second assembly electrodes AE2 using the electric field formed between the plurality of first assembly electrodes AE1 and the plurality of second assembly electrodes AE2.

The assembly insulating layer IL is disposed on the plurality of assembly electrodes AE and the assembly substrate SUB. The assembly insulating layer IL protects the plurality of assembly electrodes AE from the fluid WT to suppress the defect such as corrosion of the plurality of assembly electrodes AE.

The organic layer OL including a plurality of openings OLH is disposed on the plurality of assembly electrodes AE. The organic layer OL is an insulating layer including the plurality of openings OLH in which the plurality of light emitting diodes 120 is seated and can be formed as a single layer or a double layer. For example, the thickness of the organic layer OL can be adjusted by configuring the organic layer OL as a single layer or a double layer.

Each of the plurality of openings OLH which is formed by opening a part of the organic layer OL is an area in which the plurality of light emitting diodes 120 is self-assembled. The plurality of openings OLH can be disposed so as to overlap an area between the first assembly electrode AE1 and the second assembly electrode AE2. Further, each of the plurality of openings OLH can be formed in a position of the display panel PN corresponding to each of the plurality of sub pixels SP, later. The plurality of openings OLH can be disposed to correspond to the plurality of sub pixels SP one to one and the light emitting diode 120 which is self-assembled in the plurality of openings OLH can be aligned with the same interval as the plurality of sub pixels SP.

Further, a voltage is applied to the plurality of assembly electrodes AE to self-assemble the plurality of light emitting diodes 120 in the opening OLH of the organic layer OL. For example, different AC voltages are applied to the first assembly electrode AE1 and the second assembly electrode AE2 to form an electric field. The light emitting diode 120 is dielectrically polarized by the electric field to have a polarity. Further, the dielectrically polarized light emitting diode 120 can move or can be fixed to a specific direction by dielectrophoresis (DEP), for example, an electric field. Accordingly, the plurality of light emitting diodes 120 can be temporarily self-assembled in the opening OLH of the assembling substrate 1000 using dielectrophoresis.

In the meantime, during a process of self-assembling the plurality of light emitting diodes 120 in the assembling substrate 1000, adsorption of the plurality of light emitting diodes 120 in a place other than the opening OLH, for example, a remaining part of the assembling substrate 1000 excluding the opening OLH, the first chamber CB1, or the second chamber CB2 is minimized by forming the first uneven structure 121a on the bottom surface of the first semiconductor layer 121. Specifically, gallium nitride (GaN) which forms the first semiconductor layer 121 is formed with a grid structure to have a polarity and the gallium nitride having polarity can be more easily combined in the other place. However, when the first uneven structure 121a is formed on the bottom surface of the first semiconductor layer 121, the polarity of the bottom surface of the first semiconductor layer 121 is degraded and the bottom surface of the first semiconductor layer 121 can have a non-polarity or semi-polarity. Therefore, the first uneven structure 121a is formed on the bottom surface of the first semiconductor layer 121 so as to allow the bottom surface of the first semiconductor layer 121 to have semi-polarity or non-polarity. Further, the light emitting diode 120 can be suppressed from being attached to a place other than an area in the plurality of openings OLH or suppressed from being clustered. Further, the transferring process of the plurality of light emitting diodes 120 can be simplified. Accordingly, the first uneven structure 121a is formed in the plurality of light emitting diodes 120 to more easily transfer the plurality of light emitting diodes 120 onto the display panel PN and the non-transferring defect of the plurality of light emitting diodes 120 can be reduced.

Referring to FIG. 4D, the plurality of light emitting diodes 120 of the assembling substrate 1000 is transferred onto the donor 2000. Specifically, the assembling substrate 1000 and the donor 2000 can be aligned such that one surface of the assembling substrate 1000 in which the plurality of light emitting diodes 120 is disposed and one surface of the donor 2000 are opposite to each other. Further, the assembling substrate 1000 and the donor 2000 are bonded to transfer the light emitting diode 120 onto the donor 2000. The donor 2000 is formed of a material having adhesiveness and upper portions of the plurality of light emitting diodes 120 are bonded to the donor 2000 to transfer from the assembling substrate 1000 to the donor 2000.

When the plurality of light emitting diodes 120 is transferred from the assembling substrate 1000 to the donor 2000, the first semiconductor layers 121 of the plurality of light emitting diodes 120 are in contact with the assembling substrate 1000. At this time, the bottom surface of the first semiconductor layer 121 has a first uneven structure 121a and has a semi-polarity or a non-polarity so that the first semiconductor layer 121 of the light emitting diode 120 can be more easily separated from the assembling substrate 1000. Accordingly, the defect that the plurality of light emitting diodes 120 is not transferred from the assembling substrate 1000 to the donor 2000 can be reduced.

Next, referring to FIGS. 4E and 4F, the plurality of light emitting diodes 120 of the donor 2000 is transferred onto the display panel PN.

First, the display panel PN has completed the process of forming the adhesive layer 117 and the display panel PN and the donor 2000 are aligned so that the adhesive layer 117 and the plurality of light emitting diodes 120 of the donor 2000 are opposite to each other. After disposing the donor 2000 such that the plurality of light emitting diodes 120 of the donor 2000 is opposite to the adhesive layer 117 of the display panel PN, the donor 2000 and the display panel PN are bonded to transfer the light emitting diode 120 on the donor 2000 onto the adhesive layer 117. The plurality of light emitting diodes 120 disposed on the donor 2000 is disposed so as to correspond to the plurality of sub pixels SP so that all the light emitting diodes 120 on the donor 2000 are transferred onto the display panel PN at one time without selectively transferring the light emitting diodes 120. The plurality of light emitting diodes 120 which is transferred onto the display panel PN is attached onto the adhesive layer 117 to be temporarily fixed.

Next, referring to FIG. 4F, after transferring the light emitting diode 120 onto the adhesive layer 117 of the display panel PN, the protection film PAS of the light emitting diode 120 is removed and a contact hole is formed in the encapsulation film 126. Specifically, the protection film PAS which covers the encapsulation film 126 of the light emitting diode 120 and the second electrode layer 124b can be removed. Further, a contact hole through which the second electrode 125 is exposed can be formed in the encapsulation film 126 by etching a part of the encapsulation film 126. The second connection electrode CE2 and the second electrode 125 to be formed later can be electrically connected through the contact hole of the encapsulation film 126.

Next, a metal layer ML is formed on the light emitting diode 120 and the adhesive layer 117 and a second planarization material layer 118m is formed on the metal layer ML. The metal layer ML can be formed to cover all the light emitting diodes 120. The metal layer ML can cover all the second electrode 125, the encapsulation film 126, and the second electrode layer 124b. Further, the metal layer ML can be connected to the first reflective electrode RE1 through a contact hole formed in the adhesive layer 117 and the passivation layer 116.

The second planarization material layer 118m formed on the metal layer ML is a material layer which forms the second planarization layer 118 and is formed as the second planarization layer 118 by an ashing process. Specifically, the second planarization material layer 118m is formed and the ashing process of reducing a thickness of the entire second planarization material layer 118m can be performed. Accordingly, the second planarization layer 118 can be formed by the ashing process of reducing the thickness of the second planarization material layer 118m. A top surface of the second planarization layer 118 can be disposed at a height lower than the emission layer 122. The top surface of the second planarization layer 118 can be disposed to be lower than the bottom surface of the emission layer 122. The second planarization layer 118 can have a thickness smaller than that of the first semiconductor layer 121.

Next, the metal layer ML exposed from the second planarization layer 118 is etched to form the first connection electrode CE1. A part of the metal layer ML which encloses the second electrode 125, the second semiconductor layer 123, and the emission layer 122 of the light emitting diode 120 and is exposed from the second planarization layer 118 can be etched. In the drawings of the example embodiments, it is illustrated that in a portion in which first electrodes 124, 524, and 724 are formed on the first semiconductor layers 121, 521, and 721, the thickness of the metal layer ML is equal to the thickness of the second planarization layer 118. However, in order to suppress the metal layer ML formed on the first electrodes 124, 524, and 724 from being removed during the etching process, the second planarization layer 118 remains above the metal layer ML by the ashing process in a portion in which first electrodes 124, 524, and 724 are formed on the first semiconductor layers 121, 521, and 721. Accordingly, a remaining part of the metal layer ML which is enclosed by the second planarization layer 118 remains to serve as the first connection electrode CE1. The second planarization layer 118 is used as a mask to form the first connection electrode CE1. Further, an uppermost part of the first connection electrode CE1 can be disposed on the same planar surface as the top surface of the first planarization layer 115.

Accordingly, instead of aligning the first connection electrode CE1 so as to correspond to the first electrode layer 124a in the top and the side portion of the first semiconductor layer 121 of the light emitting diode 120, only the metal layer ML exposed from the second planarization layer 118 having a smaller thickness than that of the first semiconductor layer 121 of the light emitting diode 120 is simply removed to self-align the first connection electrode CE1.

Next, referring to FIG. 4G, a third planarization layer 119 is formed on the second planarization layer 118. Specifically, the third planarization material layer 119m which covers the light emitting diode 120 is formed and the ashing process is formed on the third planarization material layer 119m to form the third planarization layer 119. An upper portion of the third planarization material layer 119m is entirely removed by the ashing process to expose the second electrode 125 of the light emitting diode 120 from the third planarization layer 119.

Finally, referring to FIG. 4H, the second connection electrode CE2 is formed on the third planarization layer 119. The second connection electrode CE2 is in contact with the second electrode 125 of the light emitting diode 120 exposed from the third planarization layer 119. Further, the second connection electrode CE2 can be connected to the second reflective electrode RE2 through the contact hole formed in the third planarization layer 119, the second planarization layer 118, the adhesive layer 117, and the passivation layer 116. Accordingly, the second electrode 125 of the light emitting diode 120 and the second reflective electrode RE2 and the power line PL are electrically connected to each other by means of the second connection electrode CE2.

Next, the bank BB is formed on the second connection electrode CE2 and the third planarization layer 119. The bank BB is formed in a surrounding area of the light emitting diode 120 to reduce color mixture between the plurality of sub pixels SP.

In the meantime, the contact hole through which the second connection electrode CE2 and the second reflective electrode RE2 are in contact can be formed in various ways. For example, in each of the forming processes of the passivation layer 116, the adhesive layer 117, the second planarization layer 118, and the third planarization layer 119, the contact hole is partially formed and the contact holes of the layers are connected to finally form a contact hole through which the second connection electrode CE2 and the second reflective electrode RE2 are connected. Further, the contact holes are simultaneously formed in several layers and for example, the contact holes are partially formed in the passivation layer 116 and the adhesive layer 117. When the second planarization layer 118 and the third planarization layer 119 are formed by the subsequent process, the contact hole is partially formed. Further, after forming the third planarization layer 119, the contact holes can be formed entirely from the third planarization layer 119 to the passivation layer 116 at one time. A process and an order of forming the contact holes can be modified in various forms, but are not limited thereto.

In the display device 100 according to the example embodiment of the present disclosure, the first uneven structure 121a is formed on the bottom surface of the first semiconductor layer 121 to reduce the attachment of the plurality of light emitting diodes 120 in an incorrect position. Specifically, during the process of forming the first uneven structure 121a on the bottom surface of the light emitting diode 120 or self-assembling the light emitting diode 120, a defect that the light emitting diode 120 is attached in a place other than the opening OLH of the assembling substrate 1000 can occur. Specifically, the first semiconductor layer 121 of the light emitting diode 120 is formed of gallium nitride having polarity to be easily bonded to the other place. Therefore, the first uneven structure 121a is formed on the bottom surface of the first semiconductor layer 121 of the light emitting diode 120 to allow the bottom surface of the first semiconductor layer 121 to have a non-polarity or a semi-polarity. Accordingly, the defect that the plurality of light emitting diodes 120 is adhered to the first chamber CB1 and the second chamber CB2 or adhered to a place other than the opening OLH of the assembling substrate 1000 can be suppressed. Further, the light emitting diode 120 seated in the plurality of openings OLH is easily separated from the assembling substrate 1000 to be transferred onto the donor 2000. Accordingly, the first uneven structure 121a is formed below the first semiconductor layer 121 of the light emitting diode 120 to reduce the non-transferring defect of the light emitting diode 120 or the defect that the light emitting diode 120 is adhered to an incorrect position and improve the manufacturing yield of the display device 100.

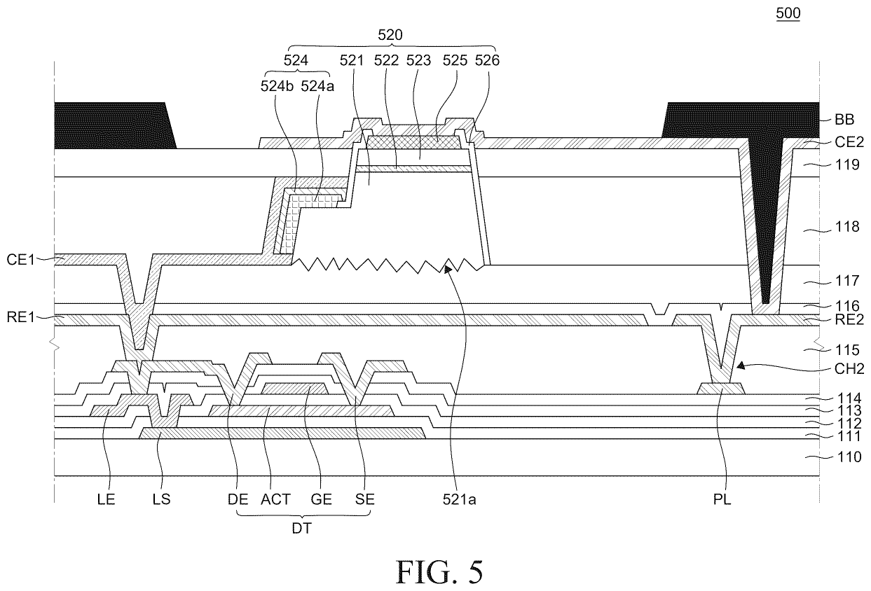

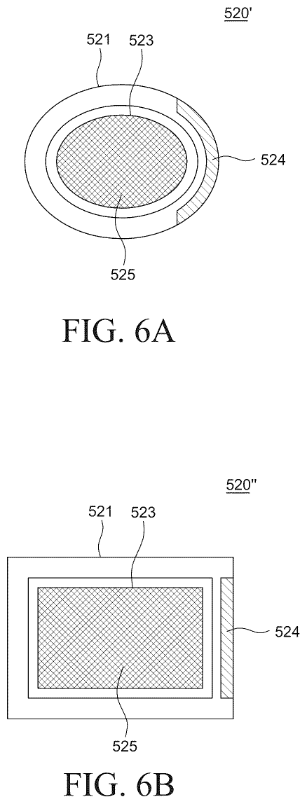

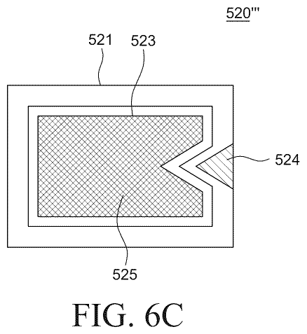

FIG. 5 is a cross-sectional view of a display device according to another example embodiment of the present disclosure. FIGS. 6A to 6C are schematic plan views of a light emitting diode of a display device according to various example of the present disclosure. The difference between a display device 500 of FIGS. 5 to 6C and the display device 100 of FIGS. 1 to 3 is a light emitting diode 520, but other configurations are substantially the same, so that a redundant description will be omitted or may be briefly provided.

Referring to FIG. 5, a first semiconductor layer 521 of a light emitting diode 520 can include a part below an emission layer 522 and a part protruding from the second semiconductor layer in one direction. A part of a side surface of the first semiconductor layer 521 can be disposed on the same line as a side surface of the emission layer 522 and a side surface of the second semiconductor layer 523. Further, the other part of the side surface of the first semiconductor layer 521 in a protruding part of the first semiconductor layer 521 protrudes outside more than a side surface of the emission layer 522 and a side surface of the second semiconductor layer 523 to be disposed on a different planar surface therefrom. The protruding part of the first semiconductor layer 521 can be a part formed for a process margin when the first electrode layer 524a and the second electrode layer 524b are formed.

The light emitting diode 520 includes a first electrode layer 524a which covers a side portion of the first semiconductor layer 521 and a second electrode layer 524b which covers the first electrode layer 524a. The first electrode layer 524a and the second electrode layer 524b can be disposed to cover only a part of the side surface of first semiconductor layer 521. The first electrode layer 524a and the second electrode layer 524b can be disposed on a side surface of the protruding part of first semiconductor layer 521, among the side surface of first semiconductor layer 521. Further, the first electrode layer 524a and the second electrode layer 524b can be disposed on a top surface of the protruding part of first semiconductor layer 521.

For example, one end portion of the second electrode layer 524b and one end portion of the first electrode layer 524a can be disposed on a top surface of the first semiconductor layer 521 which protrudes to the outside of the second semiconductor layer 523 and the emission layer 522. Further, the other end portion of the second electrode layer 524b and the other end portion of the first electrode layer 524a can be disposed to be spaced apart from a lower edge of the side surface of the first semiconductor layer 521. The other end portions of the first electrode layer 524a and the second electrode layer 524b can be disposed on a lower portion of first semiconductor layer 521 to be disposed to be spaced apart from the lower edge of the first semiconductor layer 521. In a spaced part of the lower edge of the first semiconductor layer 521 and the first electrode 524, the first connection electrode CE1 can be in contact with the bottom surfaces of the first semiconductor layer 521 and the first electrode 524.

The encapsulation film 526 is formed on a side surface of the first semiconductor layer 521 in which the first electrode layer 524a and the second electrode layer 524b are not formed to protect the first semiconductor layer 521.

Further, an area of the emission layer 522 can expand to the side surface of the first semiconductor layer 521 in which the first electrode layer 524a and the second electrode layer 524b are not formed. For example, a part of the top surface of the first semiconductor layer 521 needs to be exposed to the emission layer 522 for the process margin of the first electrode layer 524a and the second electrode layer 524b. However, in a part in which the first electrode layer 524a and the second electrode layer 524b are not formed, the emission layer 522 can be disposed on the top surface of the first semiconductor layer 521. Accordingly, the area of the emission layer 522 of the light emitting diode 520 can be increased and the luminous efficiency of the light emitting diode 520 can be improved.

Referring to FIGS. 6A to 6C, a placement area of the first electrode layer 524a and the second electrode layer 524b can be designed in various forms in consideration of the shape of the light emitting diode 520. For example, referring to FIG. 6A, when the overall planar surface shape of the light emitting diode 520′ is an oval shape, the first electrode layer 524a and the second electrode layer 524b can be disposed so as to cover only a part of the side portion of the first semiconductor layer 521. At this time, the planar surface shape of the first electrode layer 524a and the second electrode layer 524b can be an arc shape.

For example, referring to FIG. 6B, when the overall planar surface shape of the light emitting diode 520″ is a rectangular shape, the first electrode layer 524a and the second electrode layer 524b can be disposed so as to correspond to one side of the first semiconductor layer 521.

For example, referring to FIG. 6C, when the overall planar surface shape of the light emitting diode 520′″ is a rectangular shape and the emission layer 522, the second semiconductor layer 523, and the second electrode have a planar surface shape which has a groove formed in at least a part, the first electrode layer 524a and the second electrode layer 524b are disposed so as to correspond to one side of the first semiconductor layer 521 and can be also disposed in the grooves of the emission layer 522, the second semiconductor layer 523, and the second electrode 525.

However, the planar surface shape of the light emitting diode 520 and the placement area of the first electrode layer 524a and the second electrode layer 524b can be designed in various forms, but are not limited thereto.

Accordingly, in the display device 500 according to another example embodiment of the present disclosure, the first electrode layer 524a and the second electrode layer 524b are formed only in a part of the side surface of the first semiconductor layer 521 to improve the light extraction efficiency. Light emitted from the emission layer 522 travels in various directions so that there can be light which travels toward the first semiconductor layer 521. At this time, some light which is directed toward the side surface of the first semiconductor layer 521 can travel to the outside of the light emitting diode 520 through a part in which the first electrode layer 524a and the second electrode layer 524b are not disposed. Specifically, light may not transmit the second electrode layer 524b which is formed of an opaque ferromagnetic material for the sake of self-assembly of the light emitting diode 520. Further, the second electrode layer 524b is formed of a ferromagnetic material having a low reflectance so that the larger the area of the second electrode layer 524b, the lower the light extraction efficiency of the light emitting diode 520. Therefore, the second electrode layer 524b is disposed on a part of the side surface of the first semiconductor layer 521 with a minimum area so that more light can be extracted to the side surface of the first semiconductor layer 521. Accordingly, the first electrode layer 524a and the second electrode layer 524b are formed only in a part of the side surface of the light emitting diode 520 to improve a light output efficiency to the side surface of the first semiconductor layer 521. Further, the display device 500 which has a high efficiency and a high luminance to be driven at a low power can be implemented.

In the display device 500 according to another example embodiment of the present disclosure, the end portions of the first electrode layer 524a and the second electrode layer 524b are disposed to be higher than a lower edge of the first semiconductor layer 521 to suppress burrs from the end portions of the first electrode layer 524a and the second electrode layer 524b. During a process of forming the first uneven structure 521a on the bottom surface of the first semiconductor layer 521 using a solution ECT including etchant or fluid WT, burrs can be generated between the lower edge of the first semiconductor layer 521 and the end portion of the first electrode layer 524a. Further, lifting can occur between the first electrode layer 524a and the first semiconductor layer 521. Accordingly, the end portions of the first electrode layer 524a and the second electrode layer 524b are disposed to be higher than the bottom surface of the first semiconductor layer 521 to suppress burrs in the first electrode layer 524a and the second electrode layer 524b and reduce the defect of the light emitting diode 520.

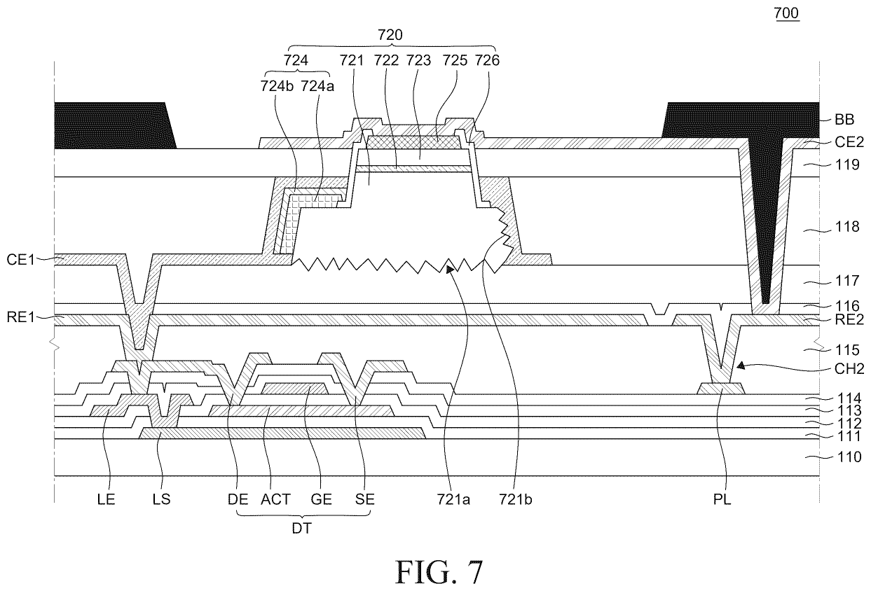

FIG. 7 is a cross-sectional view of a display device according to still another example embodiment of the present disclosure. The difference between a display device 700 of FIG. 7 and the display device 500 of FIGS. 5 and 6 is a light emitting diode 720, but other configurations are substantially the same, so that a redundant description will be omitted or may be briefly provided.

Referring to FIG. 7, a first semiconductor layer 721 of the light emitting diode 720 includes a first uneven structure 721a of a bottom surface of the first semiconductor layer 721 and a second uneven structure 721b of a bottom surface of the first semiconductor layer 721. The first uneven structure 721a can be formed on the entire bottom surface of the first semiconductor layer 721. The second uneven structure 721b can be formed on a part of the side surface of the first semiconductor layer 721 on which the first electrode layer 724a and the second electrode layer 724b are not disposed.

Further, the part in which the second uneven structure 721b is formed can be exposed from the encapsulation film 726. The side surface of the first semiconductor layer 721 can be formed by a side surface part in which the first electrode layer 724a and the second electrode layer 724b are disposed, a side surface part which is exposed from the encapsulation film 726 and has a second uneven structure 721b, and a side surface part which is covered by the encapsulation film 726.

In the meantime, both the encapsulation film 726 and the protection film PAS may not be formed in a part in which the second uneven structure 721b is formed during the manufacturing process of the light emitting diode 720. After forming the first semiconductor layer 721, the emission layer 722, the second semiconductor layer 723, the first electrode layer 724a, the second electrode layer 724b, and the second electrode 725 of the light emitting diode 720 on the wafer WF, the encapsulation film 726 and the protection film PAS which cover them can be formed. At this time, the encapsulation film 726 and the protection film PAS are omitted on a part on which the second uneven structure 721b will be formed and the side surface of the first semiconductor layer 721 exposed from the encapsulation film 726 and the protection film PAS is exposed to the solution ECT including etchant to form the second uneven structure 721b.

Accordingly, in the display device 700 according to still another example embodiment of the present disclosure, the end portion of the encapsulation film 726 is disposed to be higher than the lower edge of the first semiconductor layer 721 to suppress burrs from the end portion of the encapsulation film 726. For example, the end portion of the encapsulation film 726 is disposed to be higher than the bottom surface of the first semiconductor layer 721 to be spaced apart from the bottom surface of the first semiconductor layer 721. The encapsulation film 726 may not be formed in a lower part of the first semiconductor layer 721. When the first uneven structure 721a is formed on the bottom surface of the first semiconductor layer 721, burrs can be generated between the first uneven structure 721a of the bottom surface of the first semiconductor layer 721 and the end portion of the encapsulation film 726 and thus lifting can be generated in the encapsulation film 726. Therefore, the end portion of the encapsulation film 726 is formed to be higher than the bottom surface of the first semiconductor layer 721 to suppress burrs in the end portion of the encapsulation film 726 and reduce the lifting of the encapsulation film 726 to improve the reliability of the light emitting diode 720.

In the display device 700 according to still another example embodiment of the present disclosure, the second uneven structure 721b is formed on the side surface of the first semiconductor layer 721 exposed from the encapsulation film 726 to improve the light extraction efficiency to the side portion of the light emitting diode 720. Light emitted from the emission layer 722 travels to various directions and some light can travel to the side surface or the bottom surface of the first semiconductor layer 721 in which the first electrode layer 724a and the second electrode layer 724b are not formed. At this time, light which travels to the side surface of the first semiconductor layer 721 in which the first electrode layer 724a and the second electrode layer 724b are not formed can be more easily extracted to the outside of the first semiconductor layer 721 by the second uneven structure 721b. Further, light which travels to the bottom surface of the first semiconductor layer 721 can be more easily extracted to the outside of the first semiconductor layer 721 by the first uneven structure 721a. Accordingly, some light which travels from the emission layer 722 to the first semiconductor layer 721 is scattered and reflected by the first uneven structure 721a and the second uneven structure 721b to be more easily extracted to the outside of the light emitting diode 720. Therefore, the light extraction efficiency of the light emitting diode 720 and the luminance of the display device 700 can be improved.

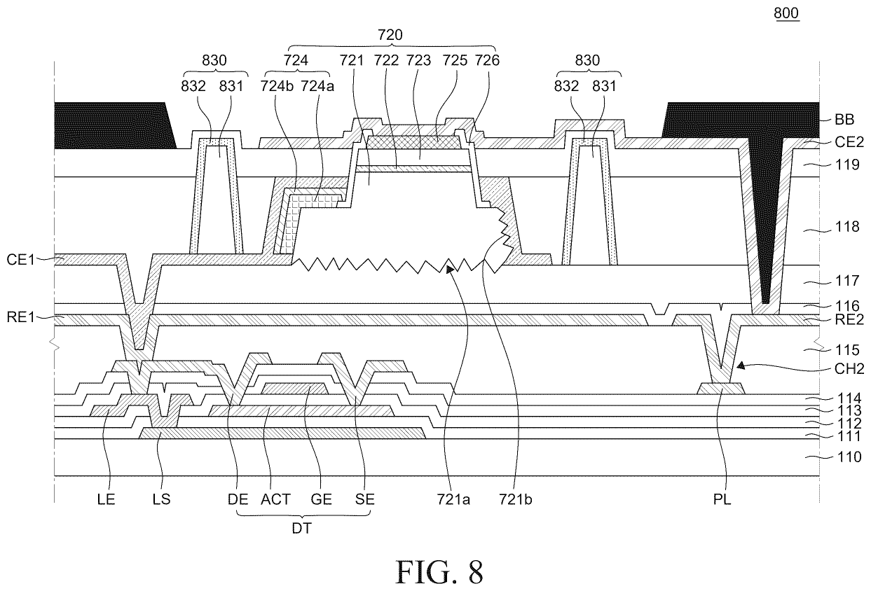

FIG. 8 is a cross-sectional view of a display device according to still another example embodiment of the present disclosure. The difference between a display device 800 of FIG. 8 and the display device 700 of FIG. 7 is that a reflective partition 830 is further included, but the other configuration is substantially the same, so that a redundant description will be omitted or may be briefly provided.

Referring to FIG. 8, a reflective partition 830 which encloses the light emitting diode 720 is disposed in each of the plurality of sub pixels SP. The reflective partition 830 can be disposed around the light emitting diode 720 to enclose the light emitting diode 720. For example, in the planar surface view, the reflective partition 830 can be formed with a closed-loop ring shape which encloses the light emitting diode 720. The reflective partition 830 can be disposed on the adhesive layer 117 and the first connection electrode CE1.

The reflective partition 830 includes a partition layer 831 and a reflective layer 832. The partition layer 831 can be disposed on the adhesive layer 117 and the first connection electrode CE1 so as to enclose the plurality of light emitting diodes 720. A height of the reflective layer 832 which is formed of a metal material can be adjusted by adjusting a thickness of the partition layer 831. The partition layer 831 can be formed of an insulating material, and for example, can be formed of photoresist or an acrylic-based organic material, but is not limited thereto. Further, the partition layer 831 is configured by a single layer or a double layer to adjust a thickness of the partition layer 831.

The reflective layer 832 can cover a top surface and a side surface of the partition layer 831. The reflective layer 832 is formed on a surface of the partition layer 831 to reflect light which is directed to the side surface of the light emitting diode 720, among light emitted from the light emitting diode 720, to the upper direction of the light emitting diode 720. The reflective layer 832 is disposed so as to enclose the lower portion and the side portion of the light emitting diode 720 together with the first reflective electrode RE1 and the second reflective electrode RE2 to reflect the light emitted from the light emitting diode 720 to the top of the light emitting diode 720. The reflective layer 832 can be formed of a metal material having an excellent reflective property, such as aluminum (Al), silver (Ag), copper (Cu), palladium (Pd), or an alloy thereof, but is not limited thereto.

In the meantime, a part of the reflective layer 832 is in contact with the first connection electrode CE1 to be electrically connected. At this time, the reflective layer 832 is enclosed by the second planarization layer 118 and the third planarization layer 119 to be separated from the other configuration, such as a second connection electrode CE2, so that the short defect due to the reflective layer 832 can be suppressed. Specifically, the third planarization layer 119 covers a top of the reflective layer 832 to insulate the reflective layer 832 and the second connection electrode CE2 from each other.

During the manufacturing process of the display device 800, a metal layer ML for forming the first connection electrode CE1 is formed and the partition layer 831 and the reflective layer 832 can be sequentially formed on the metal layer ML and the adhesive layer 117. Further, after forming the second planarization layer 118 on the reflective partition 830, a part of the metal layer ML exposed from the second planarization layer 118 is etched to form the first connection electrode CE1. Finally, the third planarization layer 119, the second connection electrode CE2, and the bank BB are sequentially formed on the reflective partition 830 and the second planarization layer 118 to complete the manufacturing process of the display device 800.

Accordingly, in the display device 800 according to still another example embodiment of the present disclosure, a reflective partition 830 which encloses the light emitting diode 720 is formed to improve the light extraction efficiency of the light emitting diode 720. Some of light emitted from the light emitting diode 720 travels to the bottom surface of the first semiconductor layer 721 or the side surface of the first semiconductor layer 721 in which the first electrode layer 724a and the second electrode layer 724b are not formed. Light which travels to the side surface of the first semiconductor layer 721 is scattered and reflected by the first uneven structure 721a and the second uneven structure 721b to be extracted to the outside of the light emitting diode 720. At this time, the light which is extracted to the outside of the light emitting diode 720 is reflected from the first reflective electrode RE1 and the second reflective electrode RE2 below the light emitting diode 720 and the reflective partition 830 on the side portion of the light emitting diode 720 to travel to the upper portion of the light emitting diode 720. The first reflective electrode RE1 or the second reflective electrode RE2 extends while overlapping a part of the reflective partition 830 at the left and right of the light emitting diode 720 to overlap the entire area of the light emitting diode 720 to reflect light emitted from the light emitting diode 720 and light reflected from the reflective partition 830. For example, the first reflective electrode RE1 can be disposed so as to overlap the entire light emitting diode 720 and the entire reflective partition 830. Further, at least some of light emitted from the light emitting diode 720 or light reflected from the reflective partition 830 can be reflected to the upper portion of the substrate 110 by the first reflective electrode RE1. Accordingly, the light extraction efficiency of the light emitting diode 720 can be improved and the luminance of the display device 800 can be improved.

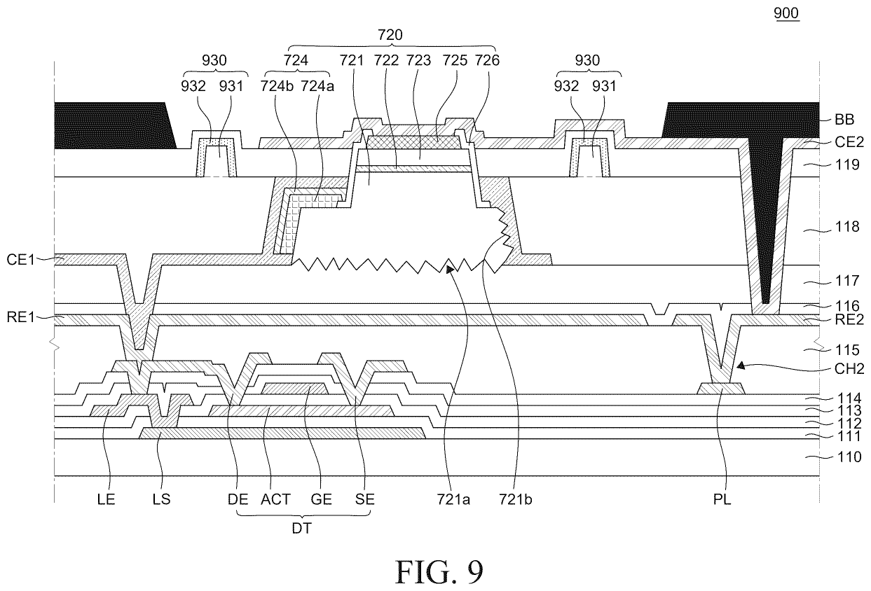

FIG. 9 is a cross-sectional view of a display device according to still another example embodiment of the present disclosure. The difference between a display device 900 of FIG. 9 and the display device 800 of FIG. 8 is a reflective partition 930, but the other configuration is substantially the same, so that a redundant description will be omitted or may be briefly provided.

Referring to FIG. 9, the reflective partition 930 is disposed on the second planarization layer 118. The reflective partition 930 can be disposed on the second planarization layer 118 to enclose the light emitting diode 720. The reflective partition 930 can reflect some light which is directed to the side surface of the light emitting diode 720 to the upper portion of the light emitting diode 720.

A partition layer 931 of the reflective partition 930 is disposed on the second planarization layer 118. For example, the partition layer 931 can be formed together when the second planarization layer 118 is formed and the partition layer 931 is integrally formed with the second planarization layer 118. The partition layer 931 is disposed to protrude from the top surface of the second planarization layer 118.

Further, after forming the second planarization layer 118 and the partition layer 931, the reflective layer 932 is formed on the partition layer 931 and the third planarization layer 119 can be formed on the reflective layer 932. The reflective layer 932 can be disposed so as to cover a top surface and a side surface of the partition layer 931.

The third planarization layer 119 is disposed on the reflective partition 930. The third planarization layer 119 can be disposed so as to cover upper portions of the reflective partition 930 and the light emitting diode 720.

Accordingly, in the display device 900 according to still another example embodiment of the present disclosure, the second planarization layer 118 and the partition layer 931 of the reflective partition 930 are formed together to simplify the manufacturing process of the reflective partition 930. For example, the second planarization layer 118 and the partition layer 931 can be formed by the same process and the same material. Therefore, the manufacturing process of the partition layer 931 of the reflective partition 930 is integrated with the manufacturing process of the second planarization layer 118 to simplify the manufacturing process of the reflective partition 930.

The example embodiments of the present disclosure can also be described as follows:

According to an aspect of the present disclosure, a display device includes a substrate in which a plurality of sub pixels is defined, and a light emitting diode which is disposed in each of the plurality of sub pixels and has a first uneven structure, and the light emitting diode includes a first semiconductor layer which has a first uneven structure formed on a bottom surface, an emission layer on the first semiconductor layer, a second semiconductor layer on the emission layer, a first electrode disposed on at least a part of a side surface of the first semiconductor layer, and a second electrode disposed on the second semiconductor layer.

A bottom surface of the first semiconductor layer can have a semi-polarity or a non-polarity.

The first electrode can include a first electrode layer which is in contact with a side surface of the first semiconductor layer, and a second electrode layer disposed on the first electrode layer, and the second electrode layer can be formed of a ferromagnetic material.

The first semiconductor layer can partially protrude from the emission layer and the second semiconductor layer and one end portion of the first electrode layer and one end portion of the second electrode layer can be disposed on a top surface of a protruding part of the first semiconductor layer.

The other end portion of the first electrode layer and the other end portion of the second electrode layer can be disposed to be spaced apart from a lower edge of the first semiconductor layer.

The light emitting diode can further include a second uneven structure formed in a remaining part of the side surface of the first semiconductor layer excluding a part in which the first electrode is disposed.

The light emitting diode can further include an encapsulation film which encloses the second semiconductor layer, the emission layer, and at least a part of the first semiconductor layer and the encapsulation film can cover the remaining part of the side surface of the first semiconductor layer excluding a part in which the second uneven structure and the first electrode are disposed.

An end portion of the encapsulation film can be disposed to be spaced apart from a lower edge of the first semiconductor layer.

The first uneven structure and the second uneven structure can be exposed from the first electrode and the encapsulation film.

The first uneven structure and the second uneven structure can be irregular uneven structures.

The display device can further include a reflective partition disposed on each of the plurality of sub pixels so as to enclose the light emitting diode, and the reflective partition can include a partition layer which encloses the light emitting diode, and a reflective layer disposed on a top surface and a side surface of the partition layer.

The reflective partition can be configured to reflect light extracted to a side surface of the first semiconductor layer to an upper portion of the light emitting diode.

The display device can further include a first planarization layer disposed between the substrate and the light emitting diode, an adhesive layer disposed between the first planarization layer and the light emitting diode, a first connection electrode which is disposed on the adhesive layer and is electrically connected to the first electrode of the light emitting diode, a second planarization layer disposed on the first connection electrode and the light emitting diode, a third planarization layer disposed on the second planarization layer, and a second connection electrode which is disposed on the third planarization layer and is electrically connected to the second electrode of the light emitting diode. The reflective layer of the reflective partition can be disposed to be spaced apart from the second connection electrode with the third planarization layer therebetween.

The partition layer of the reflective partition can be disposed on the adhesive layer and the first connection electrode.

The partition layer of the reflective partition can be disposed to protrude from a top surface of the second planarization layer.

According to an aspect of the present disclosure, a method of manufacturing a display device includes placing a wafer and a plurality of light emitting diodes formed on one surface of the wafer in a chamber filled with a solution, separating the plurality of light emitting diodes from the wafer, placing an assembling substrate above the chamber, and moving the plurality of light emitting diodes to the assembling substrate by placing a magnet on n the assembling substrate and self-assembling the plurality of light emitting diodes on the assembling substrate.

The solution in the chamber can include at least one of de-ionized water and an alkaline etchant.

An uneven structure can be formed on bottom surfaces of the plurality of light emitting diodes by the solution in the chamber.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate in which a plurality of sub pixels is defined; and
a light emitting diode disposed in each of the plurality of sub pixels and having a first uneven structure,
wherein the light emitting diode includes:
a first semiconductor layer having the first uneven structure formed on a bottom surface of the first semiconductor layer;
an emission layer on the first semiconductor layer;
a second semiconductor layer on the emission layer;
a first electrode disposed on at least a part of a side surface of the first semiconductor layer; and
a second electrode disposed on the second semiconductor layer.

2. The display device according to claim 1, wherein the bottom surface of the first semiconductor layer has a semi-polarity or a non-polarity.

3. The display device according to claim 1, wherein the first electrode includes:
a first electrode layer in contact with a side surface of the first semiconductor layer; and
a second electrode layer disposed on the first electrode layer, and
wherein the second electrode layer includes a ferromagnetic material.

4. The display device according to claim 3, wherein the first semiconductor layer partially protrudes from the emission layer and the second semiconductor layer, and one end portion of the first electrode layer and one end portion of the second electrode layer are disposed on a top surface of a protruding part of the first semiconductor layer.

5. The display device according to claim 4, wherein another end portion of the first electrode layer and another end portion of the second electrode layer are disposed to be spaced apart from a lower edge of the first semiconductor layer.

6. The display device according to claim 3, wherein the light emitting diode further includes a second uneven structure formed in a remaining part of the side surface of the first semiconductor layer excluding a part in which the first electrode is disposed.

7. The display device according to claim 6, wherein the light emitting diode further includes an encapsulation film enclosing the second semiconductor layer, the emission layer, and at least a part of the first semiconductor layer, and
wherein the encapsulation film covers the remaining part of the side surface of the first semiconductor layer excluding a part in which the second uneven structure and the first electrode are disposed.

8. The display device according to claim 7, wherein an end portion of the encapsulation film is disposed to be spaced apart from a lower edge of the first semiconductor layer.

9. The display device according to claim 7, wherein the first uneven structure and the second uneven structure are exposed from the first electrode and the encapsulation film.

10. The display device according to claim 7, wherein the first uneven structure and the second uneven structure are irregular uneven structures.

11. The display device according to claim 6, further comprising:
a reflective partition disposed on each of the plurality of sub pixels so as to enclose the light emitting diode,
wherein the reflective partition includes:
a partition layer enclosing the light emitting diode; and
a reflective layer disposed on a top surface and a side surface of the partition layer.

12. The display device according to claim 11, wherein the reflective partition is configured to reflect light extracted to a side surface of the first semiconductor layer to an upper portion of the light emitting diode.

13. The display device according to claim 11, further comprising:
a first planarization layer disposed between the substrate and the light emitting diode;
an adhesive layer disposed between the first planarization layer and the light emitting diode;
a first connection electrode disposed on the adhesive layer and electrically connected to the first electrode of the light emitting diode;
a second planarization layer disposed on the first connection electrode and the light emitting diode;
a third planarization layer disposed on the second planarization layer; and
a second d connection electrode disposed on the third planarization layer and electrically connected to the second electrode of the light emitting diode,
wherein the reflective layer of the reflective partition is disposed to be spaced apart from the second connection electrode with the third planarization layer therebetween.

14. The display device according to claim 13, wherein the partition layer of the reflective partition is disposed on the adhesive layer and the first connection electrode.

15. The display device according to claim 13, wherein the partition layer of the reflective partition is disposed to protrude from a top surface of the second planarization layer.

16. A method of manufacturing a display device, the method comprising:
placing a wafer and a plurality of light emitting diodes formed on one surface of the wafer in a chamber filled with a solution;
separating the plurality of light emitting diodes from the wafer;
placing an assembling substrate on the chamber; and
moving the plurality of light emitting diodes to the assembling substrate by placing a magnet on the assembling substrate and self-assembling the plurality of light emitting diodes on the assembling substrate.

17. The method of manufacturing the display device according to claim 16, wherein the solution in the chamber includes at least one of de-ionized water and an alkaline etchant.

18. The method of manufacturing the display device according to claim 17, wherein an uneven structure is formed on bottom surfaces of the plurality of light emitting diodes by the solution in the chamber.

19. A display device, comprising:
a substrate; and
a plurality of sub pixels disposed on the substrate;
wherein each of the plurality of sub pixels comprises a light emitting diode including:
a first semiconductor layer having a bottom surface, a top surface and a side surface;
an emission layer on the top surface; and
a first electrode disposed on at least a part of the side surface, and
wherein the bottom surface of the first semiconductor layer has a first uneven structure.

20. The display device according to claim 19, wherein the first uneven structure is an uneven structure formed by wet-etching using an alkaline etchant.
